(19) United States
(12) Patent Application Publication
(10) Pub. No.: US 2026/0082956 A1
(43) Pub. Date: Mar. 19, 2026

(54) ELECTRONIC DEVICE AND MANUFACTURING METHOD THEREOF

(71) Applicant: Innolux Corporation, Miao-Li County (TW)

(72) Inventors: Yi-Liang CHEN, Miao-li County (TW); Chia-Chi Ho, Miao-Li County (TW); Jeng-Nan Li, Miao-Li County (TW)

(73) Assignee: InnoLux Corporation, Miao-Li County (TW)

(21) Appl. No.: 19/292,936

(22) Filed: Aug. 7, 2025

Related U.S. Application Data
(60) Provisional application No. 63/695,861, filed on Sep. 18, 2024.

(30) Foreign Application Priority Data
May 7, 2025 (CN) 202510580002.0

(51) Int. Cl. H01L 23/498; H01L 21/768

(52) U.S. Cl. CPC H10W 70/65; H10W 20/056; H10W 70/685

(57) ABSTRACT

An electronic device includes an electronic component, a packaging layer, a circuit structure and a bonding component. The packaging layer surrounds the electronic component. The circuit structure is electrically connected to the electronic component, wherein the circuit structure includes a conductive pattern. The bonding component is disposed in a recess of the conductive pattern and overlaps the conductive pattern. The conductive pattern includes a first portion, a second portion and a third portion, the third portion is connected to the first portion and the second portion, the bonding component overlaps the third portion, and a width of the first portion is different from a width of the second portion.

### CROSS REFERENCE TO RELATED APPLICATION

This application claims the benefit of U.S. Provisional Application No. 63/695,861, filed on Sep. 18, 2024. The content of the application is incorporated herein by reference.

### BACKGROUND OF THE DISCLOSURE

### 1. Field of the Disclosure

The present disclosure relates to an electronic device and a manufacturing method thereof, and more particularly to an electronic device with high yield rate and high reliability, and to a manufacturing method of this electronic device.

### 2. Description of the Prior Art

As the evolution and development of electronic devices, the electronic devices have become indispensable items. The electronic device may include a computing element and/or a controlling component (e.g., an integrated circuit (IC), a chip, etc.), so as to have required functions (e.g., a display function, a sensing function or other suitable function).

Normally, the computing element and/or the controlling component may be electrically connected to a suitable electronic component through a circuit structure and a bonding component, so as to form a suitable circuit. However, in a conventional electronic device, since the circuit structure (or a conductive part of the circuit structure configured to connected to the bonding component) is a planar structure, a contact area between the circuit structure and the bonding component is small, such that the damage (e.g., the fracture) may occur between the circuit structure and the bonding component, thereby affecting the yield rate and the reliability of the conventional electronic device. Thus, an appropriate design of the circuit structure is required to improve the yield rate and the reliability of the electronic device.

### SUMMARY OF THE DISCLOSURE

According to an embodiment, the present disclosure provides an electronic device including an electronic component, a packaging layer, a circuit structure and a bonding component. The packaging layer surrounds the electronic component. The circuit structure is electrically connected to the electronic component, wherein the circuit structure includes a conductive pattern. The bonding component is disposed in a recess of the conductive pattern and overlaps the conductive pattern. The conductive pattern includes a first portion, a second portion and a third portion, the third portion is connected to the first portion and the second portion, the bonding component overlaps the third portion, and a width of the first portion is different from a width of the second portion.

According to an embodiment, the present disclosure provides a manufacturing method of an electronic device. The manufacturing method includes: providing a carrier substrate; providing a barrier layer on the carrier substrate; providing a circuit structure on the barrier layer, wherein a conductive pattern of the circuit structure overlaps the barrier layer; removing the barrier layer to make the conductive pattern have a recess; and providing a bonding component in the recess.

### BRIEF DESCRIPTION OF THE DRAWINGS

FIG. 1 is a schematic diagram showing a cross-sectional view of an electronic device according to a first embodiment of the present disclosure.

FIG. 2 is a schematic diagram showing a top view of edges of an electronic device (or a circuit structure), a conductive pattern of a circuit structure and a bonding component according to a first embodiment of the present disclosure.

FIG. 3 to FIG. 9 are schematic diagrams showing cross-sectional views of structures at some steps of a manufacturing method of an electronic device according to a first embodiment of the present disclosure.

FIG. 10 is a schematic diagram showing a cross-sectional view of a design of a barrier layer according to a second embodiment of the present disclosure.

FIG. 11 to FIG. 13 are schematic diagrams showing cross-sectional views of a design of a barrier layer and structures at some steps of a manufacturing method of an electronic device according to a third embodiment of the present disclosure.

FIG. 14 to FIG. 16 are schematic diagrams showing cross-sectional views of structures at some steps of a manufacturing method of an electronic device according to a fourth embodiment of the present disclosure.

FIG. 17 is a schematic diagram showing cross-sectional views of some designs related to a recess of a conductive pattern and a bonding component according to some embodiments of the present disclosure.

FIG. 18 is a schematic diagram showing a top view of an electronic device according to an embodiment of the present disclosure.

FIG. 19 is a schematic diagram showing a cross-sectional view of an electronic device according to a fifth embodiment of the present disclosure.

FIG. 20 is a schematic diagram showing a cross-sectional view of an electronic device according to a sixth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components with the same function but different names.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, they specify the existence of the corresponding features, regions, steps, operations and/or components, but do not exclude the existence of one or a plurality of the corresponding features, regions, steps, operations and/or components.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the show drawings the general characteristics of methods, structures, and/or materials used in specific embodiments. However, the drawings should not be construed as defining or limiting the scope or properties encompassed by these embodiments. For example, the relative size, thickness, and position of each layer, each region, and/or each structure may be reduced or enlarged for clarity.

When the corresponding component such as layer or region is referred to “on another component”, it may be directly on this another component, or other component(s) may exist between them. On the other hand, when the component is referred to “directly on another component (or the variant thereof)”, any component does not exist between them. Furthermore, when the corresponding component is referred to “on another component”, the two components have a disposition relationship along a top-view/vertical direction, the corresponding component may be below or above the another component, and the disposition relationship along the top-view/vertical direction are determined by an orientation of the device.

It will be understood that when a component or layer is referred to as being “connected to” another component or layer, it can be directly connected to this another component or layer, or intervening components or layers may be presented. In contrast, when a component is referred to as being “directly connected to” another component or layer, there are no intervening components or layers presented. In addition, when the component is referred to “be coupled to/with another component (or the variant thereof)”, it may be directly connected to this another component, or may be indirectly connected (such as electrically connected) to this another component through other component(s).

In the description and following claims, the term “horizontal direction” generally means a direction parallel to a horizontal plane, the term “horizontal plane” generally means a surface parallel to a direction X and direction Y in the drawings, the term “vertical direction” and the term “top-view direction” generally means a direction parallel to a direction Z and perpendicular to the horizontal direction in the drawings, and the direction X, the direction Y and the direction Z are perpendicular to each other. In the description and following claims, the term “top view” generally means a viewing result of viewing along the vertical direction. In the description and following claims, the term “cross-sectional view” generally means a viewing result of cutting a structure along the vertical direction and viewing it along the horizontal direction.

In the description and following claims, it should be noted that the term “overlap” means that two elements overlap along the direction Z, and the term “overlap” can be “partially overlap” or “completely overlap” in unspecified circumstances.

In the description and following claims, the term “width” means that a greatest dimension of a component along a horizontal direction in a cross-sectional view, the term “thickness” means that a greatest dimension of a component along a vertical direction in a cross-sectional view (e.g., a greatest distance between an lower edge and an upper edge of this component), and the term “depth” means that a greatest dimension of an accommodation space of a component along a vertical direction in a cross-sectional view (e.g., a greatest distance between an opening and a bottom of this accommodation space).

In the description and following claims, the term “surround” means that a component B1 surrounds a component C1 in a top view and is in contact with a side surface of the component C1 in a cross-sectional view.

The terms “about”, “approximately”, “substantially”, “equal”, or “same” generally mean within ±20% of a given value or range, or mean within ±10%, ±5%, ±3%, ±2%, ±1%, or ±0.5% of a given value or range.

In the description and following claims, the term “rough” means that a distance between a top of a peak and a bottom of a valley among a surface of a component in a normal direction of this surface ranges from 0.15 μm to 1 μm. Whether a component is rough could be determined by observing and measuring the surface of the component within a specific length range (e.g., 10 μm) under appropriate magnification using a scanning electron microscope (SEM), a transmission electron microscope (TEM) or other suitable microscope. Furthermore, the term “appropriate magnification” means that at least ten peaks among the observed surface could be seen under this magnification.

In the description and following claims, Young's modulus could be measured by a universal testing machine (UTM) or other suitable equipment. For instance, Young's modulus could be measured through ASTM E111 standard test method.

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, a first constituent element in the description may be a second constituent element in the claims.

It should be noted that the technical features in different embodiments described in the following can be replaced, recombined, or mixed with one another to constitute another embodiment. Features between embodiments may be mixed and matched as long as they do not violate the spirit of the invention or conflict with each other.

In the present disclosure, the electronic device may include a display device, a lighting device, an antenna device, a sensing device, a tiled device, a power module, a semiconductor packaging device or a combination thereof, but not limited thereto. The light emitting device may be capable of generating light, so as to serve as a light source (e.g., a backlight module), a display device capable of displaying or other suitable light emitting device. The display device may be a non-self-luminous type display device or a self-luminous type display device based on requirement(s), and the display device may be a color display device or a monochrome display device based on requirement(s). The antenna device may be a liquid-crystal-type antenna device or a non-liquid-crystal-type antenna device, the sensing device may be a device for sensing capacitance, light, heat or ultrasound, and the tiled device may be a tiled display device, a tiled antenna device or other suitable tiled device. The semiconductor packaging device may be a device packaging a component having semiconductor (e.g., an integrated circuit, a chip or other suitable component), and the semiconductor packaging device may be included in another device (e.g., a display device, a lighting device, an antenna device, a sensing device, a tiled device or a power module) to be a part in this device, wherein the component having semiconductor may be packaged in the semiconductor packaging device through a wafer level package (WLP) process, a panel level package (PLP) process, 2.5D package process, 3D package process, 3.5D package process or other suitable package process, and this component may be packaged according to a flow of a chip first package process, a flow of a chip last package process or a flow of a combination of both based on requirement(s).

Electronic components in the electronic device may include passive component(s) and active component(s), such as capacitor(s), resistor(s), inductor(s), diode(s), switching component(s) (e.g., transistor(s)) and/or integrated circuit(s), but not limited thereto. The diode may include a light emitting diode (LED) or a photodiode. The light emitting diode may include an organic light emitting diode (OLED), a mini LED, a micro LED or a quantum dot LED, but not limited thereto. The transistor may include a top gate thin film transistor, a bottom gate thin film transistor or a dual gate thin film transistor, but not limited thereto. The electronic device may include fluorescence material, phosphorescence material, quantum dot (QD) material or other suitable material based on requirement(s), but not limited thereto. The electronic device may have a peripheral system (such as a driving system, a control system, a light system, etc.) for supporting the device(s) and the component(s) in the electronic device.

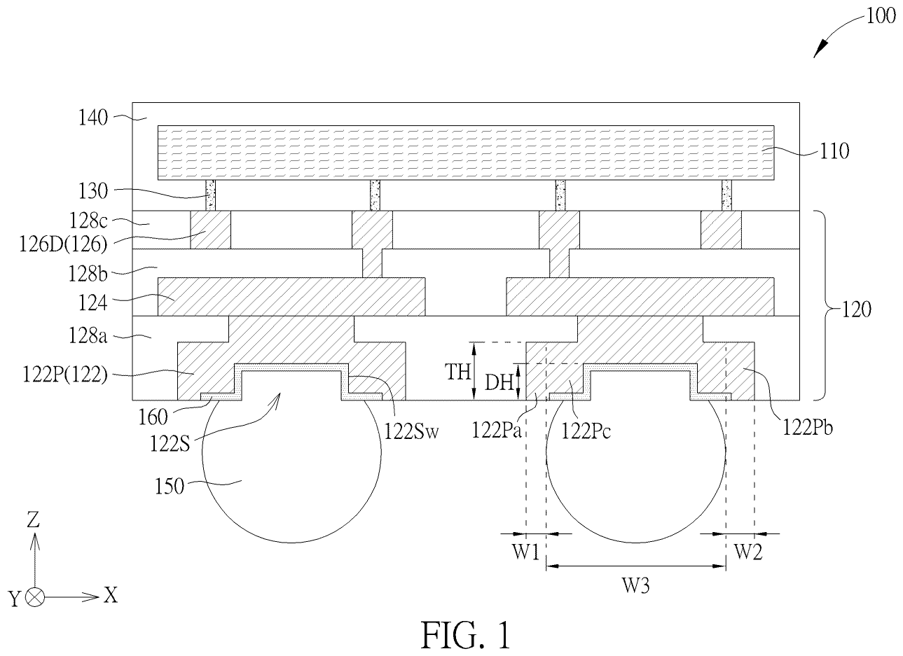

Referring to FIG. 1, FIG. 1 is a schematic diagram showing a cross-sectional view of an electronic device according to a first embodiment of the present disclosure. As shown in FIG. 1, the electronic device 100 includes at least one electronic component 110, but not limited thereto. For instance, the electronic component 110 may have a computing function, a controlling function, a storing function, any other required function or a combination thereof. For instance, the electronic component 110 may include a semiconductor layer, and the electronic component 110 may be an integrated circuit, a chip or other suitable component, but not limited thereto. According to some embodiments, the electronic device 100 may include at least one electronic component 110 and another electronic component, and the another electronic component may include an active component or a passive component, wherein the another electronic component may have a semiconductor layer when the another electronic component is an active component, and the another electronic component may not have a semiconductor layer when the another electronic component is a passive component. For instance, the electronic component 110 may be packaged in the electronic device 100 through the aforementioned package process (e.g., the electronic component 110 shown in FIG. 1 is packaged in the electronic device 100 through the chip last package process), but not limited thereto. Moreover, the semiconductor layer of this electronic component 110 may include any suitable semiconductor material. For instance, the semiconductor material may include poly-silicon, amorphous silicon, metal-oxide semiconductor, other suitable semiconductor material or a combination thereof. Note that a normal direction of the electronic component 110 may be parallel to the direction Z. Note that a surface of this electronic component 110 having pad(s) may be referred as an active surface, and a surface of this electronic component 110 opposite to the active surface may be referred as a back side.

As shown in FIG. 1, the electronic device 100 includes a circuit structure 120, wherein the circuit structure 120 is electrically connected to the electronic component 110 (e.g., the circuit structure 120 may be electrically connected to the semiconductor layer), or another component is electrically connected to the electronic component 110 through the circuit structure 120. The circuit structure 120 may include at least one conductive layer containing conductive material(s), at least one insulating layer containing insulating material(s), other suitable layer or a combination thereof. For instance, the conductive material of the circuit structure 120 may include metal (e.g., copper), transparent conductive material (e.g., indium tin oxide (ITO), indium zinc oxide (IZO), etc.), other suitable conductive material(s) or a combination thereof, and the insulating material of the circuit structure 120 may include silicon oxide (SiOₓ), silicon nitride (SiN_{y}), silicon oxynitride (SiOₓN_{y}), photoresist, organic insulating material (e.g., photosensitive polyimide (PSPI), polyimide (PI), polybenzoxazole (PBO)), other suitable insulating material(s) or a combination thereof, but not limited thereto. For instance, a coefficient of thermal expansion (CTE) of the insulating layer of the circuit structure 120 may range from 25 ppm/° C. to 50 ppm/° C., and a Young's modulus of the insulating layer may range from 0.5 GPa to 5 GPa, but not limited thereto.

In some embodiments, the circuit structure 120 may serve as a redistribution layer (RDL). Therefore, through the design of the conductive layer(s) in the circuit structure 120, the circuit structure 120 may have an effect of redistributing conductive traces, have an effect of increasing a fan-out area of conductive traces and/or make different electronic components be electrically connected to each other. In some embodiments, the circuit structure 120 may be a suitable structure including at least one conductive layer.

For instance, in FIG. 1, the circuit structure 120 may include a plurality of conductive layers (e.g., the conductive layers 122, 124 and 126 stacked in sequence) and a plurality of insulating layers (e.g., the insulating layers 128a, 128b and 128c stacked in sequence), wherein the insulating layer 128a may be configured to separate a portion of the conductive layer 122 and a portion of the conductive layer 124, and the insulating layer 128b may be configured to separate a portion of the conductive layer 124 and a portion of the conductive layer 126. For instance, since the electronic component 110 shown in FIG. 1 may be packaged in the electronic device 100 through the chip last package process, the conductive layer 126 may include a plurality of connecting pads 126D, and the electronic component 110 may be electrically connected to the connecting pads 126D of the conductive layer 126 through connecting elements 130 (i.e., the connecting element 130 may be connected between the pad of the electronic component 110 and the connecting pad 126D of the conductive layer 126), such that the circuit structure 120 may be electrically connected to the electronic component 110, but not limited thereto. For instance, the connecting element 130 may be a solder, but not limited thereto. Furthermore, the circuit structure 120 may optionally have a rough surface (e.g., at least one of the insulating layer 128a, the insulating layer 128c, the conductive layer 122 and the conductive layer 126 may have a rough surface), so as to enhance an adhesive force between the circuit structure 120 and other component (e.g., the connecting element 130).

As shown in FIG. 1, the electronic device 100 may include a packaging layer 140 surrounding the electronic component 110 (e.g., surrounding the semiconductor layer) for protecting the semiconductor layer and the electronic component 110. According to some embodiments (as shown in FIG. 1), the electronic component 110 may be cladded by the packaging layer 140, such that each surface of the electronic component 110 may overlap the packaging layer 140 in its normal direction, but not limited thereto. According to some embodiments, in the cross-sectional view, the packaging layer 140 may be in contact with a side surface of the electronic component 110 and expose a surface of the electronic component 110 connected to the side surface, but not limited thereto. In the present disclosure, the packaging layer 140 may include any suitable package material. For instance, the package material may include epoxy resin, polymer, silicon oxide (SiOₓ), silicon nitride (SiN_{y}), organic material, inorganic material, filler, other suitable package material(s) or a combination thereof, but not limited thereto. For instance, a particle size of the packaging layer 140 may range from 0.05 μm to 25 μm, a CTE of the packaging layer 140 may range from 4 ppm/° C. to 12 ppm/° C., and a Young's modulus of the packaging layer 140 may range from 5 GPa to 20 GPa, but not limited thereto.

As shown in FIG. 1, the electronic device 100 includes a bonding component 150 disposed on a side of the circuit structure 120 opposite to the electronic component 110 (i.e., the circuit structure 120 is between the bonding component 150 and the electronic component 110) and electrically connected to the circuit structure 120. In FIG. 1, the bonding component 150 may be electrically connected to the conductive layer 122 of the circuit structure 120, and be electrically connected to the electronic component 110 through the conductive layers 122, 124 and 126 of the circuit structure 120. In some embodiments, if the circuit structure 120 is a redistribution layer, according to the effect of the redistribution layer, the circuit structure 120 may make the bonding components 150 be electrically connected to the electronic component 110, and the positions of the bonding components 150 may be designed based on requirement for optionally making a distance between two adjacent bonding components 150 be greater than a distance between two adjacent connecting elements 130. In the present disclosure, the bonding component 150 may include any suitable conductive material, and this conductive material is suitable for bonding function. For instance, the conductive material of the bonding component 150 may include a solder, but not limited thereto. In the present disclosure, the bonding component 150 may have a suitable shape. For instance, the bonding component 150 may be spherical, such that the bonding component 150 may be a solder ball, but not limited thereto.

In the present disclosure, in order to improve the bonding effect between the bonding component 150 and the circuit structure 120, the conductive layer 122 of the circuit structure 120 may be appropriately designed. In FIG. 1, the conductive layer 122 of the circuit structure 120 may include at least one conductive pattern 122P, each conductive pattern 122P may have a recess 122S, the bonding component 150 may overlap the conductive pattern 122P and be disposed in the recess 122S of the conductive pattern 122P. In FIG. 1, a portion of the bonding component 150 may be disposed in the recess 122S. In some embodiments, one-to-one correspondence is used between the recesses 122S of the conductive patterns 122P and the bonding components 150. Since the bonding component 150 is disposed in the recess 122S of the conductive pattern 122P, a contact area between the bonding component 150 and the circuit structure 120 is enhanced, so as to improve the bonding effect between the bonding component 150 and the circuit structure 120, thereby reducing the occurring possibility of damage (e.g., fracture) between the bonding component 150 and the circuit structure 120.

In the present disclosure, the recess 122S may be designed based on requirement(s), so as to enhance the contact area between the bonding component 150 and the circuit structure 120. In the present disclosure, a cross-sectional shape of the recess 122S may be designed based on requirement(s). In some embodiments, the cross-sectional shape of the recess 122S may be a polygon (e.g., a rectangle, a trapezoid, etc.), a shape having a curved edge (e.g., a semicircle, a semioval, a shape with arc edges, etc.), an irregular shape or other suitable shape, but not limited thereto. For instance, the recess 122S may have any suitable cross-sectional shape, an angle between a sidewall 122Sw of the recess 122S and the direction Z may be greater than or equal to 0 degrees and less than or equal to 75 degrees, but not limited thereto. For instance, the cross-sectional shape of the recess 122S shown in FIG. 1 may be a rectangle, such that the angle between the sidewall 122Sw of the recess 122S and the direction Z is 0 degree or close to 0 degree, but not limited thereto.

In the present disclosure, a depth of the recess 122S may be designed based on requirement(s). As shown in FIG. 1, the conductive pattern 122P may include a first portion 122Pa, a second portion 122Pb and a third portion 122Pc, and the third portion 122Pc may be connected to the first portion 122Pa and the second portion 122Pb (e.g., the third portion 122Pc shown in FIG. 1 may be connected between the first portion 122Pa and the second portion 122Pb), wherein the bonding component 150 may overlap the third portion 122Pc (i.e., a portion of the conductive pattern 122P overlapping the bonding component 150 is referred as the third portion 122Pc) and may not overlap the first portion 122Pa and the second portion 122Pb, and the recess 122S may be in the third portion 122Pc. In some embodiments, the depth DH of the recess 122S may be related to a thickness of the first portion 122Pa and/or a thickness of the second portion 122Pb. For instance, in the direction Z, a ratio of the depth DH of the recess 122S to a thickness TH of the first portion 122Pa may be greater than or equal to 0.1 and less than or equal to 0.4, but not limited thereto.

In the present disclosure, a width of the first portion 122Pa, a width of the second portion 122Pb and a width of the third portion 122Pc of the conductive pattern 122P may be designed based on requirement(s). In the conductive pattern 122P, the width W1 of the first portion 122Pa may be the same as or different from the width W2 of the second portion 122Pb (e.g., in FIG. 1, the width W1 of the first portion 122Pa is different from the width W2 of the second portion 122Pb). In some embodiments, a relation between the width of the first portion 122Pa and the width of the second portion 122Pb may be related to the position of this conductive pattern 122P. For instance, in the top view of FIG. 2, the second portion 122Pb may be closer to an edge EG of the electronic device 100 (or an edge of the circuit structure 120) than the first portion 122Pa, and the width W2 of the second portion 122Pb may be greater than the width W1 of the first portion 122Pa, but not limited thereto.

In some embodiments, a total width (or a total width of the conductive pattern 122P) may be a sum of the width W1 of the first portion 122Pa, the width W2 of the second portion 122Pb and the width W3 of the third portion 122Pc, and the width W3 of the third portion 122Pc may be related to this total width. For instance, a ratio of the width W3 of the third portion 122Pc to the total width may be greater than or equal to 0.3 and less than or equal to 1, or greater than or equal to 0.35 and less than or equal to 0.9, but not limited thereto.

Moreover, in FIG. 1, the electronic device 100 may further include another conductive layer 160 disposed between the circuit structure 120 and the bonding component 150 (i.e., the conductive layer 160 may be disposed between the conductive pattern 122P of the conductive layer 122 and the bonding component 150), wherein the conductive layer 160 may overlap the conductive pattern 122P and be disposed in the recess 122S of the conductive pattern 122P. Therefore, in FIG. 1, a portion of the bonding component 150 and at least a portion of the conductive layer 160 may exist in the recess 122S, and the bonding component 150 may be electrically connected to the conductive pattern 122P of the conductive layer 122 through the conductive layer 160. For instance, the conductive layer 160 may be in direct contact with the recess 122S of the conductive pattern 122S, but not limited thereto. In the direction Z, a thickness of the conductive layer 160 may be greater than or equal to 0.1 μm and less than or equal to 2 μm, and a ratio of the thickness of the conductive layer 160 to the thickness TH of the first portion 122Pa may be greater than or equal to 0.05 and less than or equal to 0.4, but not limited thereto.

In the present disclosure, the conductive layer 160 may include conductive material(s). For instance, the conductive material of the conductive layer 160 may include metal (e.g., copper, nickel, gold, silver, etc.), other suitable conductive material(s) or a combination thereof. For instance, the conductive material of the conductive layer 160 may be the same as the conductive material of the conductive layer 122 including the conductive pattern 122P (e.g., the conductive material of the conductive layer 122 and the conductive material of the conductive layer 160 are copper), but not limited thereto. Furthermore, in some embodiments, a forming process of the conductive layer 160 may be different from a forming process of the conductive layer 122 including the conductive pattern 122P. Thus, even if the conductive material of the conductive layer 160 and the conductive material of the conductive layer 122 are the same, a particle size of the conductive layer 160 is different from a particle size of the conductive layer 122 (the conductive pattern 122P), and/or a crystallinity of the conductive layer 160 is different from a crystallinity of the conductive layer 122 (the conductive pattern 122P). For instance, the conductive layer 160 may be formed by a deposition process or a chemical plating process, and the conductive layer 122 may be formed by an electroplating process, such that the particle size of the conductive layer 160 may be less than the particle size of the conductive layer 122 including the conductive pattern 122P, the crystallinity of the conductive layer 160 may be less than the crystallinity of the conductive layer 122 including the conductive pattern 122P, but not limited thereto. For instance, a particle size of a layer may be measured by SEM or other suitable microscope, and the crystallinity may be measured by light diffraction or other suitable method, but not limited thereto. Through the above design, a bonding force between the bonding component 150 and the conductive layer 122 (the conductive pattern 122P) may be increased, or the reliability of the electronic device 100 is improved, but not limited thereto.

In the following, a manufacturing method of the electronic device 100 shown in FIG. 1 is described, and the manufacturing method of the electronic device 100 of the present disclosure is not limited to the following embodiment(s).

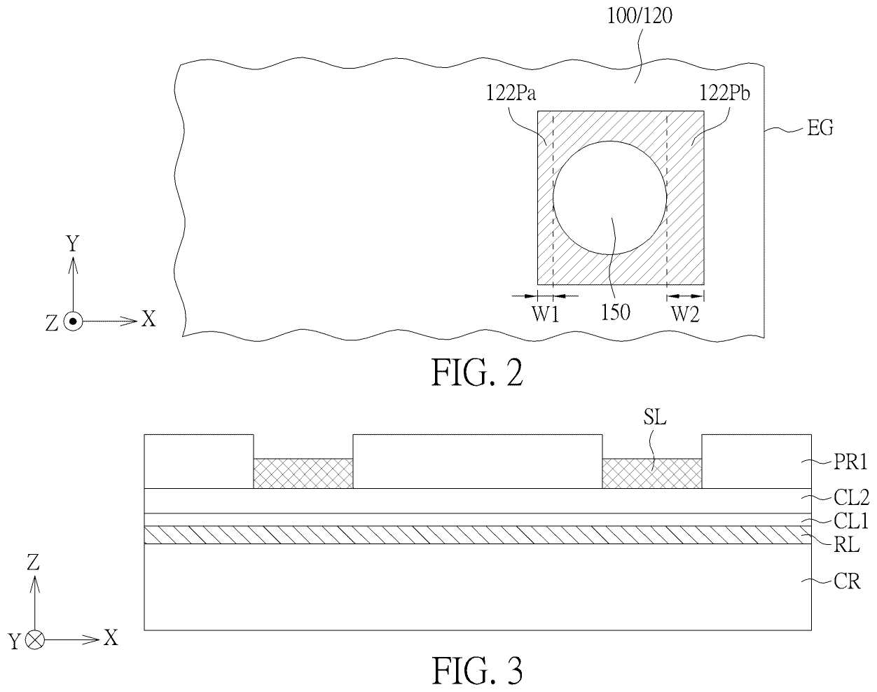

Referring to FIG. 3 to FIG. 9, FIG. 3 to FIG. 9 are schematic diagrams showing cross-sectional views of structures at some steps of a manufacturing method of an electronic device according to a first embodiment of the present disclosure. Note that the manufacturing method of the present disclosure is not limited to the following embodiment(s) and figures. In some embodiments, any other suitable step may be added before or after one of the existing steps of the manufacturing method, and/or some steps may be performed simultaneously or separately. In some embodiments, the process sequence of the manufacturing method may be adjusted based on requirement(s). Note that, in the manufacturing method of the electronic device 100 shown in FIG. 3 to FIG. 9, the electronic component 110 is packaged by the chip last package process, but not limited thereto.

In the following manufacturing method, a forming process of a layer and/or a structure may include an atomic layer deposition (ALD), a chemical vapor deposition (CVD), a physical vapor deposition (PVD), a coating process, an electroplating process, any other suitable process or a combination thereof. In the following manufacturing method, a patterning process may include a photolithography, an etching process, a developing process, any other suitable process or a combination thereof, wherein the etching process may be a wet etching process, a dry etching process, any other suitable etching process or a combination thereof.

As shown in FIG. 3, a carrier substrate CR is provided. In the present disclosure, the carrier substrate CR may be rigid or flexible, and the carrier substrate CR may include suitable material(s) according to the type thereof. For instance, the carrier substrate CR may include glass, quartz, ceramic, sapphire, silicon, glass fiber, polymer (e.g., PI, polyethylene terephthalate (PET), etc.), other suitable material(s) or a combination thereof, but not limited thereto.

As shown in FIG. 3, a release layer RL is formed on the carrier substrate CR (i.e., the release layer RL is provided), wherein the release layer RL is configured to reduce the difficulty of a subsequent process of separating the carrier substrate CR, thereby improving the yield rate of the electronic device 100. In some embodiments, an adhesive force of the release layer RL may be reduced by any suitable manner. For instance, the adhesive force of the release layer RL may be reduced by irradiation, heating, laser or other suitable manner, but not limited thereto. In the present disclosure, the release layer RL may include any suitable material. In some embodiments, the material of the release layer RL may be related to the manner of reducing the adhesive force of the release layer RL. According to some embodiments, the release layer RL may be ignored.

As shown in FIG. 3, at least one conductive layer (e.g., the conductive layers CL1 and CL2) is formed on the carrier substrate CR. In some embodiments, the conductive layer may be disposed on the release layer RL. For instance, two conductive layers CL1 and CL2 are formed on the carrier substrate CR and the release layer RL, but not limited thereto. In the present disclosure, the material of the conductive layer CL1 and the material of the conductive layer CL2 may be designed based on requirement(s), and the conductive layers CL1 and CL2 may include the same material or different materials. In some embodiments, the conductive layers CL1 and CL2 may include metal. For instance, in FIG. 3, the conductive layer CL1 may include titanium, the conductive layer CL2 may include copper, but not limited thereto. In the present disclosure, the conductive layers CL1 and CL2 may be formed by any suitable forming process. In some embodiments, at least one of the conductive layers CL1 and CL2 may serve as a seed layer to facilitate subsequent processes.

As shown in FIG. 3, a first photoresist layer PR1 is formed on the carrier substrate CR, and the first photoresist layer PR1 is patterned. In FIG. 3, the first photoresist layer PR1 is formed on the conductive layer CL2. In the present disclosure, the first photoresist layer PR1 may be a positive photoresist layer or a negative photoresist layer based on requirement(s), and a material of the first photoresist layer PR1 may be related to the type of the first photoresist layer PR1.

As shown in FIG. 3, a patterned barrier layer SL is formed on the carrier substrate CR (i.e., the barrier layer SL is provided on the carrier substrate CR). In FIG. 3, the barrier layer SL may be formed on the part(s) of the conductive layer CL2 which is not covered by the first photoresist layer PR1, such that the conductive layers CL1 and CL2 are between the barrier layer SL and the release layer RL. In the present disclosure, the barrier layer SL may include any suitable material. In some embodiments, the barrier layer SL may include metal. For instance, the barrier layer SL may include titanium, but not limited thereto. In the present disclosure, the barrier layer SL may be formed by any suitable process. For instance, if the barrier layer SL includes metal, the barrier layer SL may be formed by a coating process, an adhering process, a deposition process, a chemical plating process, an electroplating process, other suitable process or a combination thereof, but not limited thereto.

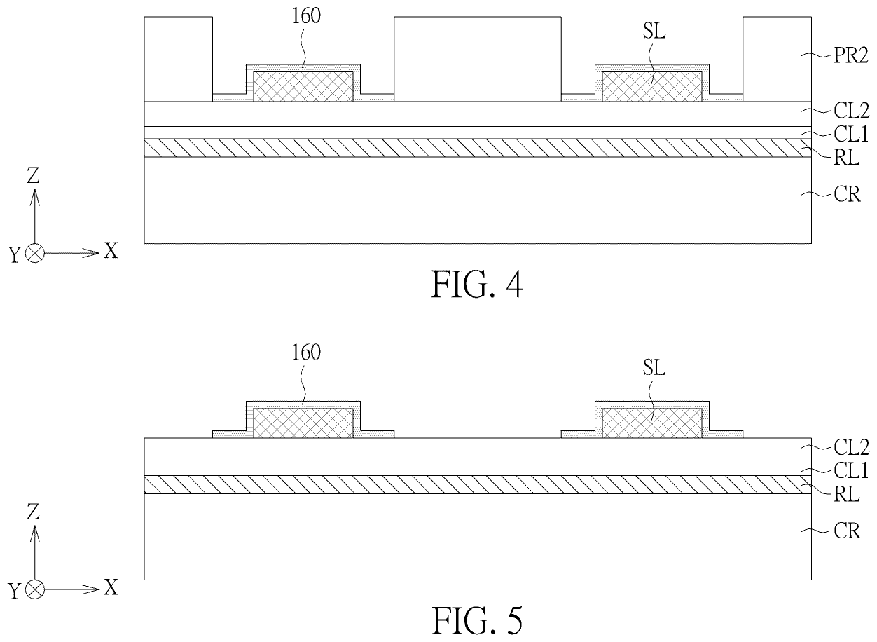

As shown in FIG. 4, the first photoresist layer PR1 is removed, a second photoresist layer PR2 is formed on the carrier substrate CR, and a patterning process is performed on the second photoresist layer PR2. In FIG. 4, the second photoresist layer PR2 may be formed on the conductive layer CL2, and a space may exist between the second photoresist layer PR2 and the barrier layer SL in a horizontal direction (e.g., the direction X). In the present disclosure, the second photoresist layer PR2 may be a positive photoresist layer or a negative photoresist layer based on requirement(s), and a material of the second photoresist layer PR2 may be related to the type of the second photoresist layer PR2.

As shown in FIG. 4, the aforementioned conductive layer 160 is formed on the barrier layer SL (i.e., the conductive layer 160 is provided on the barrier layer SL), wherein the material(s) and other features of the conductive layer 160 may refer to the above. In FIG. 4, the conductive layer 160 may be formed on the barrier layer SL and the conductive layer CL2, and the conductive layer 160 does not overlap the second photoresist layer PR2 in the direction Z. In the present disclosure, the conductive layer 160 may be formed by any suitable process. For instance, if the conductive layer 160 includes metal, the conductive layer 160 may be formed by a coating process, an adhering process, a deposition process, a chemical plating process, an electroplating process, other suitable process or a combination thereof, but not limited thereto.

As shown in FIG. 5, the second photoresist layer PR2 is removed. Optionally, a portion of the conductive layers CL1 and CL2 which is not covered by the conductive layer 160 and the barrier layer SL is removed by any suitable process. For instance, a portion of the conductive layers CL1 and CL2 which is not covered by the conductive layer 160 and the barrier layer SL is removed by an etching process, but not limited thereto.

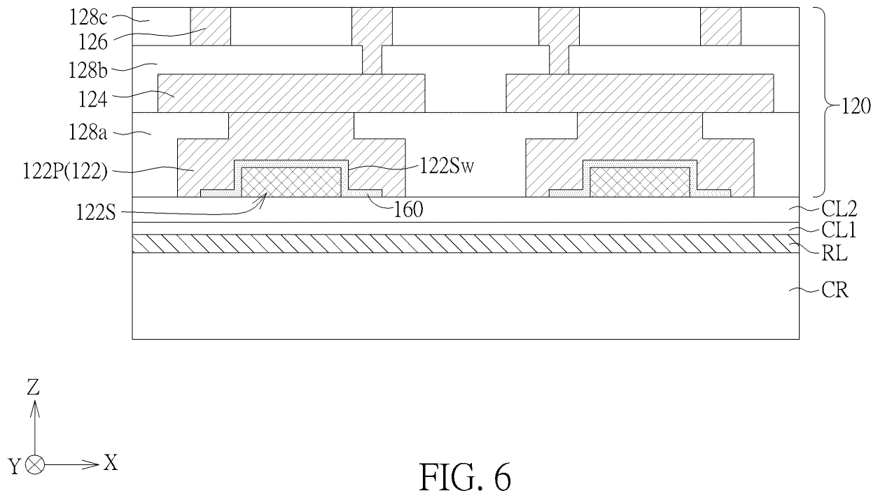

As shown in FIG. 6, the aforementioned circuit structure 120 is formed on the barrier layer SL (i.e., the circuit structure 120 is provided on the barrier layer SL), wherein the structures, materials and other features of the circuit structure 120 may refer to the above. In FIG. 6, the circuit structure 120 may be disposed on the barrier layer SL and the conductive layer 160, such that the conductive layer 160 may be disposed between the barrier layer SL and the circuit structure 120. In the present disclosure, the circuit structure 120 may be formed by any suitable process. For instance, the circuit structure 120 is formed by a photolithography, an etching process, a surface treatment process, a laser process, a forming process (e.g., an electroplating process, a coating process and/or a deposition process), other suitable process or a combination thereof, wherein the surface treatment process may be configured to roughen the surface of the circuit structure 120 (e.g., the insulating layer 128c, the conductive layer 126, etc.). In the present disclosure, the conductive layers 122, 124 and 126 and the insulating layer 128a, 128b and 128c in the circuit structure 120 may be formed in any suitable order. Each of the conductive layers 122, 124 and 126 may include a single-layer structure or a multi-layer structure. For example, when the conductive layers 122, 124 and 126 are multi-layer structures, they may include at least one seed layer. The material of the conductive layer 122, the material of the conductive layer 124 and the material of the conductive layer 126 may include titanium, copper, tungsten, nickel, vanadium, ruthenium, alloy thereof, compound thereof or a combination thereof, but not limited thereto.

In FIG. 6, the conductive pattern 122P of the conductive layer 122 overlaps the barrier layer SL in the direction Z, such that the conductive pattern 122P has the recess 122S. In FIG. 6, since the conductive layer 160 overlaps the barrier layer SL in the direction Z, the conductive layer 160 overlaps the recess 122S of the conductive pattern 122P in the direction Z (e.g., the conductive layer 160 may be in direct contact with the recess 122S of the conductive pattern 122P).

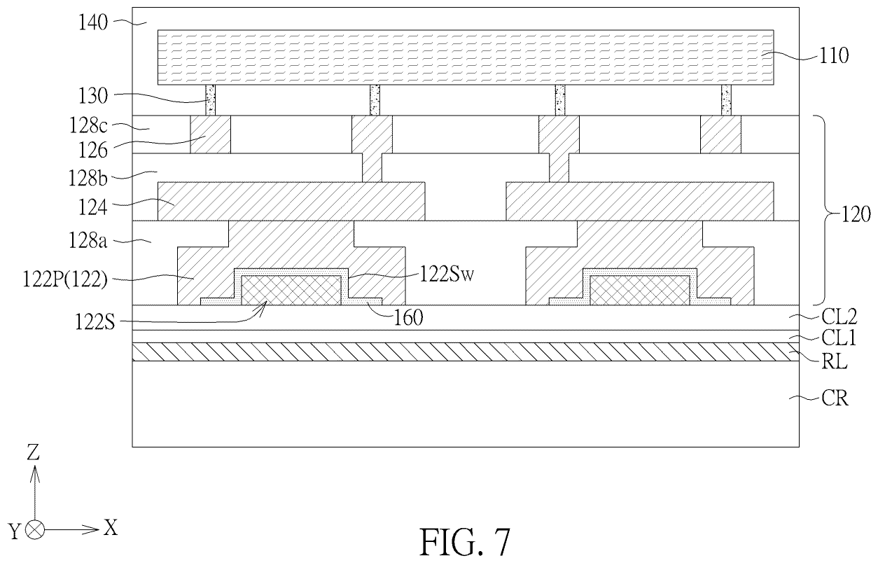

As shown in FIG. 7, the aforementioned electronic component 110 is disposed on the circuit structure 120 and electrically connected to the circuit structure 120. The electronic component 110 may be disposed on the circuit structure 120 through any suitable process. For instance, the electronic component 110 may be disposed on the circuit structure 120 through a bonding process, and thus, the electronic component 110 may be bonded to the connecting pad 126D of the conductive layer 126 through the connecting element 130 (e.g., solder) for being electrically connected to the connecting pad 126D of the conductive layer 126, so as to make the electronic component 110 be electrically connected to the circuit structure 120.

As shown in FIG. 7, the aforementioned packaging layer 140 is formed, wherein the packaging layer 140 surrounds the electronic component 110, so as to protect the semiconductor layer and the electronic component 110. For example (as shown in FIG. 7), the electronic component 110 may be cladded by the packaging layer 140, such that each surface of the electronic component 110 may overlap the packaging layer 140 in its normal direction, but not limited thereto.

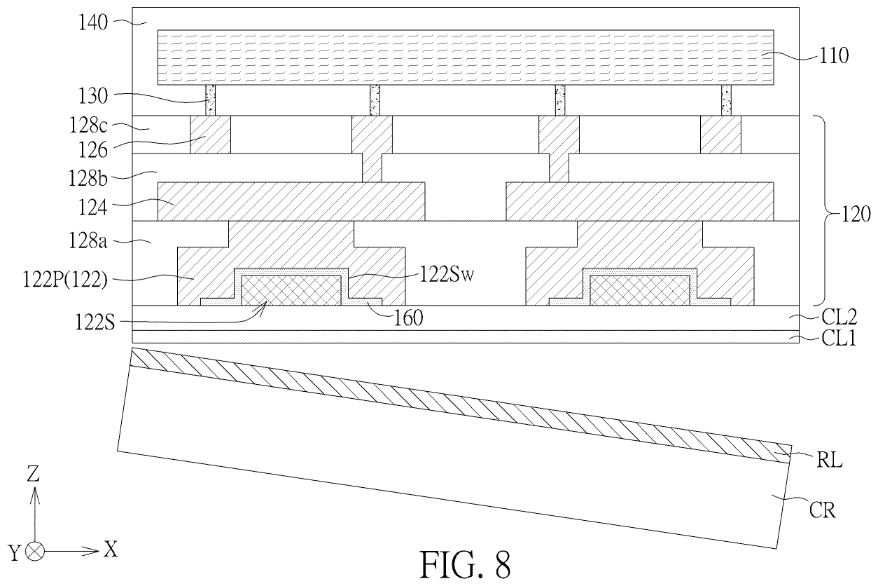

As shown in FIG. 8, the carrier substrate CR is removed. In some embodiments, the carrier substrate CR may be removed by a release process, wherein the release process may reduce the adhesive force of the release layer RL by any suitable manner. For instance, the adhesive force of the release layer RL may be reduced by irradiation, heating, laser or other suitable manner, but not limited thereto.

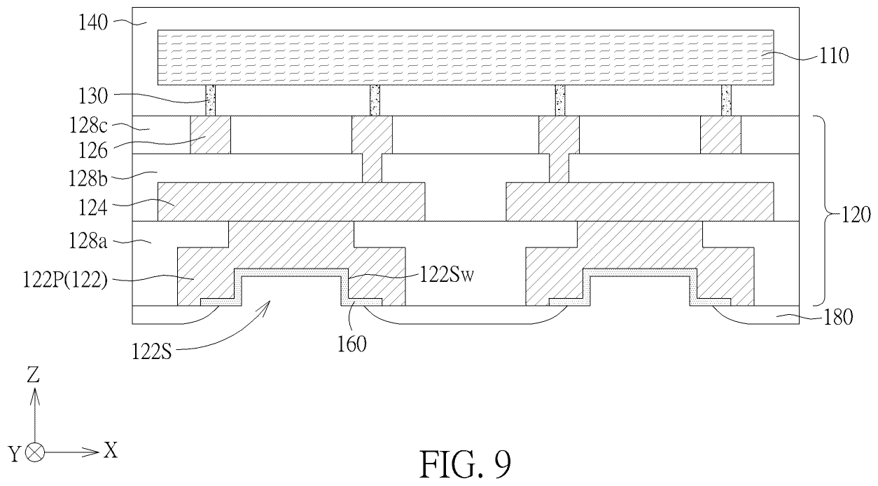

As shown in FIG. 9, the conductive layers CL1 and CL2 and the barrier layer SL are removed, so as to produce an accommodation space formed by the recess 122S of the conductive pattern 122P, wherein the conductive layers CL1 and CL2 and the barrier layer SL may be removed by the same process or different processes. For instance, the conductive layers CL1 and CL2 and the barrier layer SL may be removed by the same etching process or different etching processes. According to some embodiments, after removing the conductive layers CL1 and CL2 and the barrier layer SL, a buffer layer 180 may be optionally further provided on a side of the circuit structure 120 opposite to the packaging layer 140, wherein a Young's modulus of the buffer layer 180 may be less than the Young's modulus of an insulating layer of the packaging layer 140. Therefore, the buffer layer 180 may buffer the stress when the circuit structure 120 is bonded to an external component (e.g., a circuit board), so as to reduce the risk of cracking between the bonding component 150 and the circuit structure 120, but not limited thereto.

As shown in FIG. 1, the bonding component 150 is formed on a side of the circuit structure 120 opposite to the electronic component 110 (i.e., the circuit structure 120 is between the electronic component 110 and the bonding component 150, and the conductive layer 160 is between the bonding component 150 and the conductive layer 122 including the conductive pattern 122P), and the bonding component 150 is electrically connected to the circuit structure 120, wherein a portion of the bonding component 150 is disposed in the recess 122S of the conductive pattern 122P (i.e., the bonding component 150 is provided in the recess 122S). Accordingly, the electronic device 100 may be manufactured through above processes.

The electronic device and the manufacturing method thereof of the present disclosure are not limited to the above embodiments. Further embodiments of the present disclosure are described below. For ease of comparison, same components will be labeled with the same symbol in the following. The following descriptions relate the differences between each of the embodiments, and repeated parts will not be redundantly described.

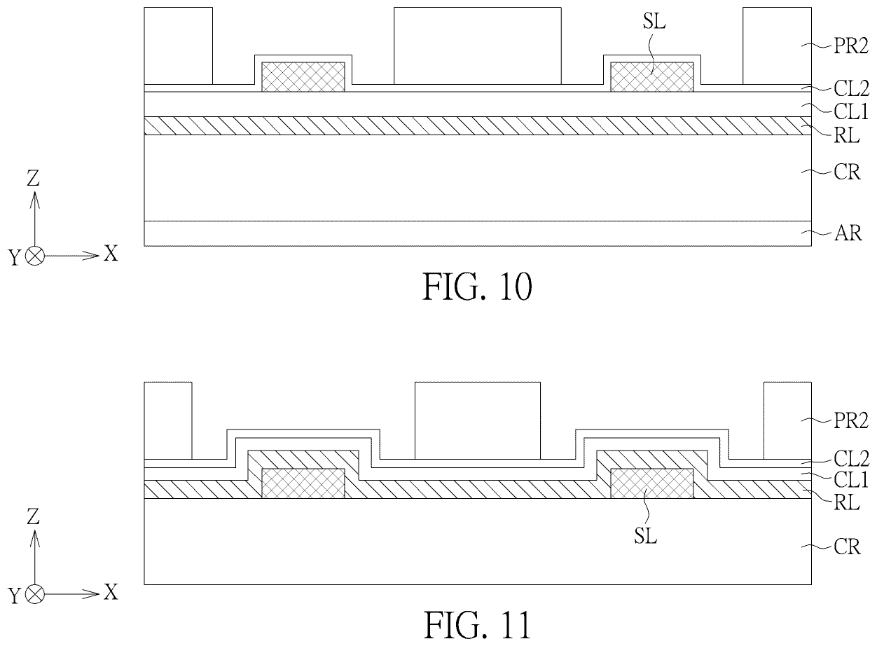

Referring to FIG. 10, FIG. 10 is a schematic diagram showing a cross-sectional view of a design of a barrier layer according to a second embodiment of the present disclosure. As shown in FIG. 10, a difference between this embodiment and the first embodiment is the design of the barrier layer SL. In FIG. 10, the barrier layer SL may be disposed between the conductive layers CL1 and CL2 (i.e., the barrier layer SL is formed before forming the conductive layer CL2). Because of the existence of the barrier layer SL, the conductive layers CL2 and 122 formed subsequently may rise and fall in cross-sectional view, so as to make the conductive pattern 122P of the conductive layer 122 have the recess 122S. For instance, the material of the barrier layer SL may be the same as the material of the conductive layer CL1. For instance, in the process(es) of removing the conductive layers CL1 and CL2 and the barrier layer SL, since the material of the barrier layer SL is the same as the material of the conductive layer CL1, the conductive layer CL1 and the barrier layer SL may be removed by the same etching process.

Optionally, according to some embodiments, an adjusting layer AR may be disposed on a side of the carrier substrate CR opposite to the conductive layers CL1 and CL2, wherein the adjusting layer AR may include organic material(s) or inorganic material(s). A warping tendency of the adjusting layer AR may be different from the warping tendency of at least one of the conductive layer CL1, the conductive layer CL2 and the circuit structure 120, so as to achieve a good warping control quality. The term “warping tendency” means that a layer causes the edge of the carrier substrate to warp up or down in the direction Z. The materials having opposite warping tendencies are respectively provided on two opposite sides of the carrier substrate CR, so as to balance the stresses, but not limited thereto.

Referring to FIG. 11 to FIG. 13, FIG. 11 to FIG. 13 are schematic diagrams showing cross-sectional views of a design of a barrier layer and structures at some steps of a manufacturing method of an electronic device according to a third embodiment of the present disclosure. As shown in FIG. 11 to FIG. 13, a difference between this embodiment and the first embodiment is the design of the barrier layer SL. In FIG. 11, the barrier layer SL may be disposed between the release layer RL and the carrier substrate CR (i.e., the barrier layer SL may be formed before forming the release layer RL), such that the release layer RL may be between the conductive layer CL1 and the barrier layer SL. Because of the existence of the barrier layer SL, the conductive layers CL1, CL2 and 122 formed subsequently may rise and fall in cross-sectional view, so as to make the conductive pattern 122P of the conductive layer 122 have the recess 122S. In this embodiment, the barrier layer SL may be a conductive structure or an insulating structure, and include any suitable material. For instance, the barrier layer SL may include insulating material(s) (e.g., photoresist), but not limited thereto.

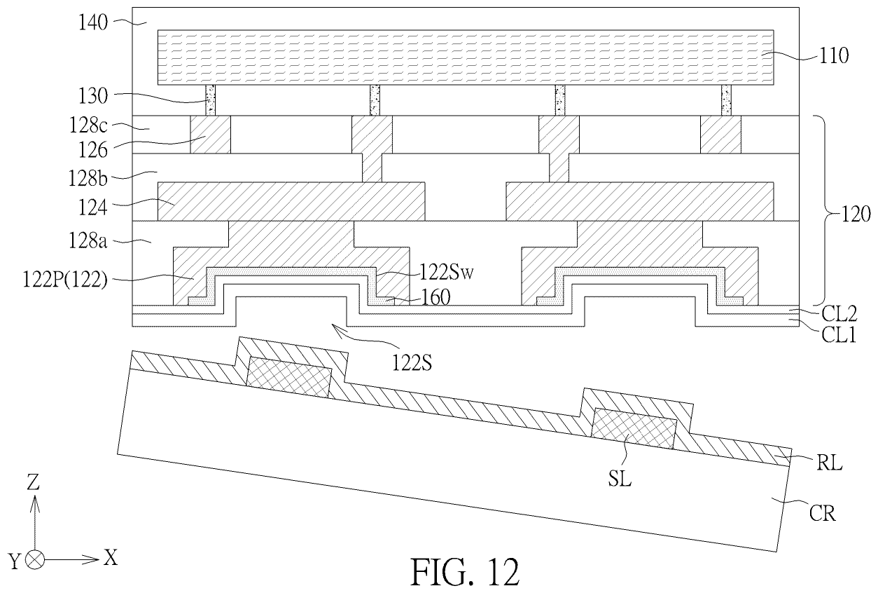

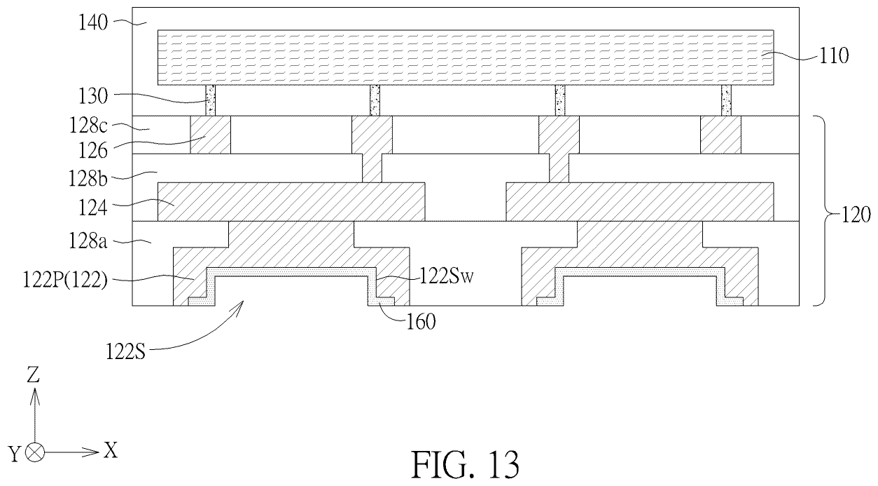

As shown in FIG. 12, in the process of removing the carrier substrate CR, since the barrier layer SL is disposed between the release layer RL and the carrier substrate CR, the carrier substrate CR and the barrier layer SL may be removed simultaneously, so as to produce the accommodation space formed by the recess 122S of the conductive pattern 122P. Then, as shown in FIG. 13, the conductive layers CL1 and CL2 are removed. Finally, the bonding component 150 is formed on a side of the circuit structure 120 opposite to the electronic component 110, wherein a portion of the bonding component 150 is disposed in the recess 122S of the conductive pattern 122P, thereby completing the manufacture of the electronic device.

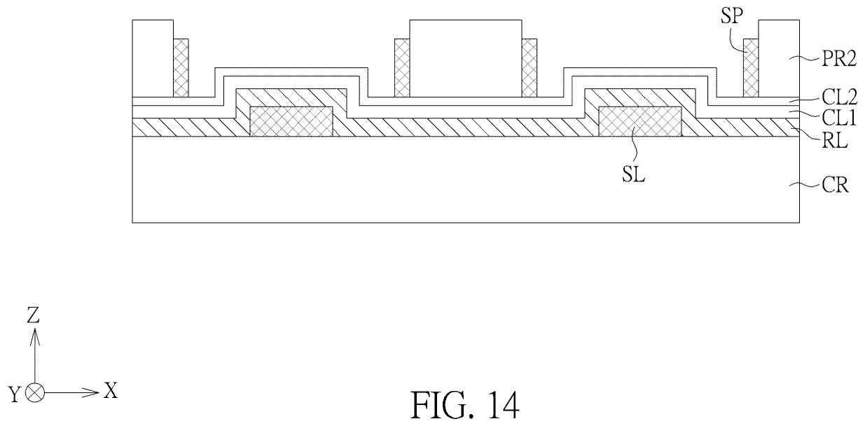

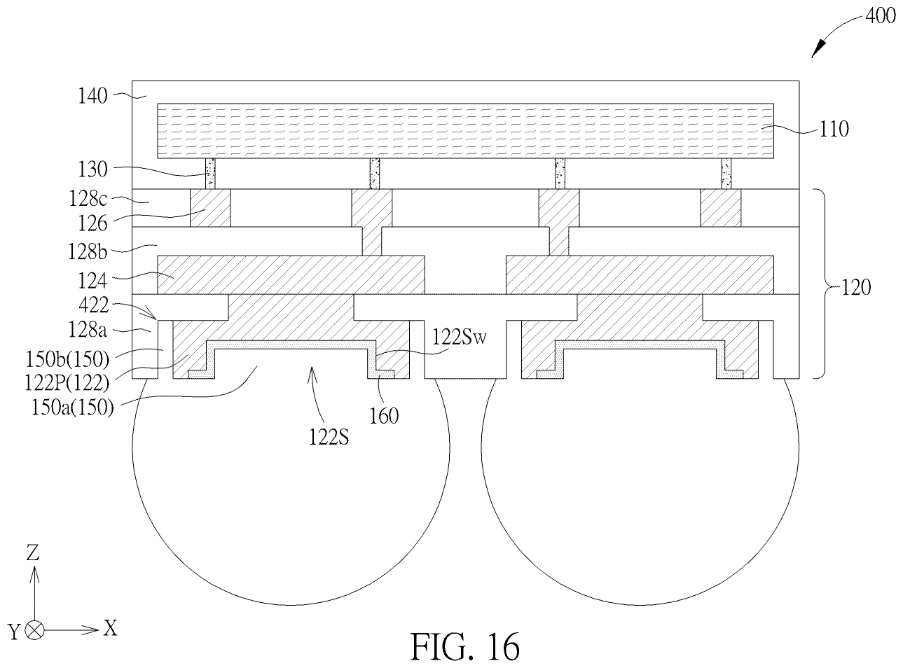

Referring to FIG. 14 to FIG. 16, FIG. 14 to FIG. 16 are schematic diagrams showing cross-sectional views of structures at some steps of a manufacturing method of an electronic device according to a fourth embodiment of the present disclosure, wherein FIG. 16 shows the electronic device 400 of the fourth embodiment. As shown in FIG. 14 to FIG. 16, a difference between this embodiment and the third embodiment is that a portion of the bonding component 150 is disposed between the conductive pattern 122P of the conductive layer 122 and the insulating layer 128a. In FIG. 16, a portion 150b of the bonding component 150 may be in direct contact with a side edge of the conductive pattern 122P and the insulating layer 128a, and the portion 150b of the bonding component 150 may not be directly connected to a portion 150a of the bonding component 150 disposed in the recess 122S, but not limited thereto. For instance, the bonding component 150 may be in direct contact with two opposite side edges of the conductive pattern 122P, but not limited thereto. Since the bonding component 150 is in direct contact with the side edge of the conductive pattern 122P, the contact area between the bonding component 150 and the circuit structure 120 is further enhanced, so as to increase the bonding effect between the bonding component 150 and the circuit structure 120 and reduce the occurring possibility of damage (e.g., fracture) between the bonding component 150 and the circuit structure 120, thereby improving the yield rate of the electronic device 400.

Although FIG. 16 does not show the first portion 122Pa, the second portion 122Pb and the third portion 122Pc of the conductive pattern 122P, it does not mean that the first portion 122Pa, the second portion 122Pb and the third portion 122Pc of the conductive pattern 122P do not exist. The first portion 122Pa, the second portion 122Pb and the third portion 122Pc of the conductive pattern 122P may be seen from other cross-sectional view.

During the manufacturing process, as shown in FIG. 14, a blocking part SP is formed on the carrier substrate CR, wherein the forming sequence of the blocking part SP and other layers may be designed based on requirement(s). For instance, in FIG. 14, the blocking part SP may be formed after forming the conductive layer CL2, but not limited thereto.

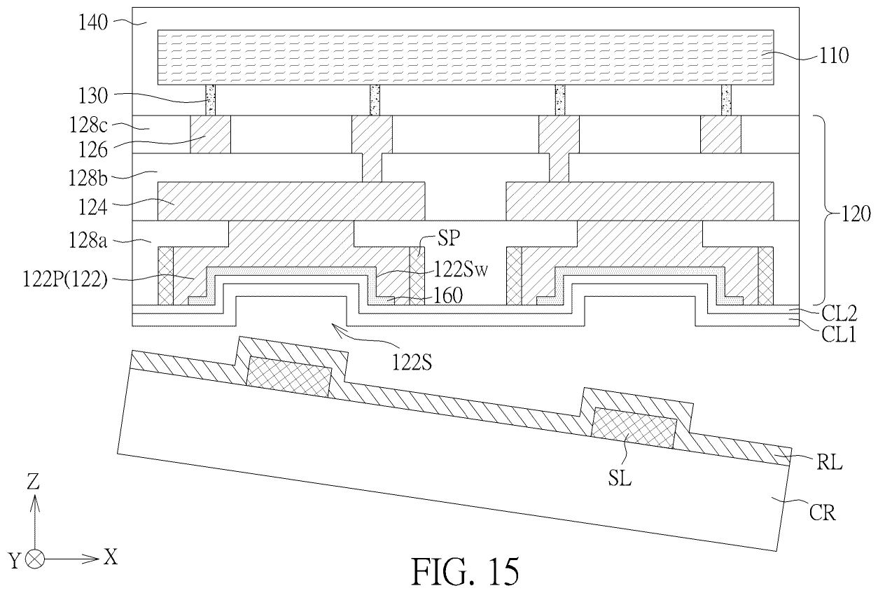

In FIG. 15, during the process of removing the carrier substrate CR, since the barrier layer SL is disposed between the release layer RL and the carrier substrate CR, the carrier substrate CR and the barrier layer SL may be removed simultaneously, so as to produce the accommodation space formed by the recess 122S of the conductive pattern 122P. Then, as shown in FIG. 16, the conductive layers CL1 and CL2 and the blocking part SP are removed, wherein an opening 422 is formed between the insulating layer 128a and the conductive pattern 122P by removing the blocking part SP, and the opening 422 is not connected to the recess 122S. As shown in FIG. 16, the bonding component 150 is formed on a side of the circuit structure 120 opposite to the electronic component 110, wherein the portion 150a of the bonding component 150 is disposed in the recess 122S of the conductive pattern 122P, and the portion 150b of the bonding component 150 is filled in the opening 422, thereby completing the manufacture of the electronic device 400.

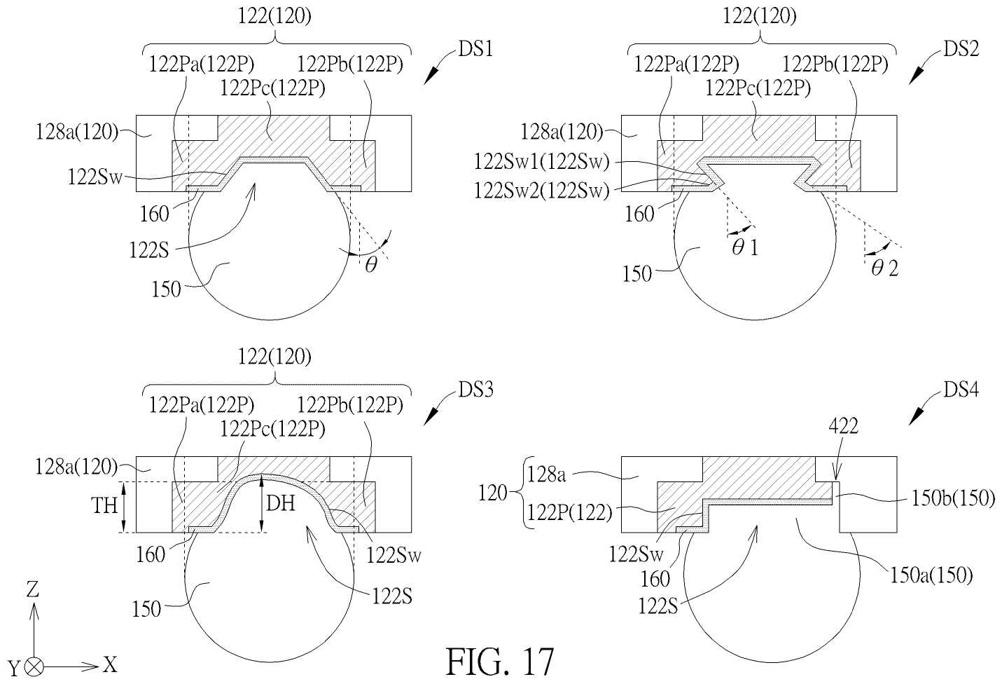

Referring to FIG. 17, FIG. 17 is a schematic diagram showing cross-sectional views of some designs related to a recess of a conductive pattern and a bonding component according to some embodiments of the present disclosure, wherein FIG. 17 shows four designs DS1, DS2, DS3 and DS4. In the design DS1 shown in FIG. 17, the cross-sectional shape of the recess 122S may be a trapezoid (e.g., in the accommodation space formed by the recess 122S, a cross-sectional area of a bottom is less than a cross-sectional area of an opening), such that the angle θ between the sidewall 122Sw of the recess 122S and the direction Z may be greater than or equal to 0 degrees and less than or equal to 75 degrees, but not limited thereto.

In the design DS2 shown in FIG. 17, the cross-sectional shape of the recess 122S may be a concave polygon. For instance, the sidewall 122Sw of the recess 122S may have a V-shaped structure (or a zigzagging structure) in the cross-sectional view, but not limited thereto. For instance, the sidewall 122Sw of the recess 122S may have a first part 122Sw1 and a second part 122Sw2 connected to each other, wherein an extending direction of the first part 122Sw1 and an extending direction of the second part 122Sw2 are different, and an angle θ1 between the first part 122Sw1 and the direction Z may be the same as or different from an angle θ2 between the second part 122Sw2 and the direction Z (e.g., in the design DS2 shown in FIG. 17, the angle θ1 between the first part 122Sw1 and the direction Z may be less than the angle θ2 between the second part 122Sw2 and the direction Z), but not limited thereto. Based on the design of the concave polygon of the recess 122S in cross-sectional view, the bonding effect between the bonding component 150 and the circuit structure 120 may be improved (i.e., the bonding component 150 may be stuck in the recess 122S to improve the bonding effect), so as to reduce the occurring possibility of damage (e.g., fracture) between the bonding component 150 and the circuit structure 120.

In the design DS3 shown in FIG. 17, the cross-sectional shape of the recess 122S may be any suitable shape, and the depth DH of the recess 122S may be greater than the thickness TH of the first portion 122Pa. For instance, in the design DS3 shown in FIG. 17, the cross-sectional shape of the recess 122S may be a shape having a curved edge or an irregular shape, but not limited thereto. Based on the design of the depth DH of the recess 122S, the contact area between the bonding component 150 and the circuit structure 120 is enhanced, so as to improve the bonding effect between the bonding component 150 and the circuit structure 120, thereby reducing the occurring possibility of damage (e.g., fracture) between the bonding component 150 and the circuit structure 120.

In the design DS4 shown in FIG. 17, a portion of the bonding component 150 may be disposed between the conductive pattern 122P of the conductive layer 122 and the insulating layer 128a. In the design DS4 shown in FIG. 17, a portion 150b of the bonding component 150 may be in direct contact with a side edge of the conductive pattern 122P and the insulating layer 128a, and the portion 150b of the bonding component 150 may be directly connected to a portion 150a of the bonding component 150 disposed in the recess 122S. For instance, the bonding component 150 may be in direct contact with one of two opposite side edges of the conductive pattern 122P, but not limited thereto. Since the bonding component 150 is in direct contact with the side edge of the conductive pattern 122P, the contact area between the bonding component 150 and the circuit structure 120 is further enhanced, so as to increase the bonding effect between the bonding component 150 and the circuit structure 120 and reduce the occurring possibility of damage (e.g., fracture) between the bonding component 150 and the circuit structure 120.

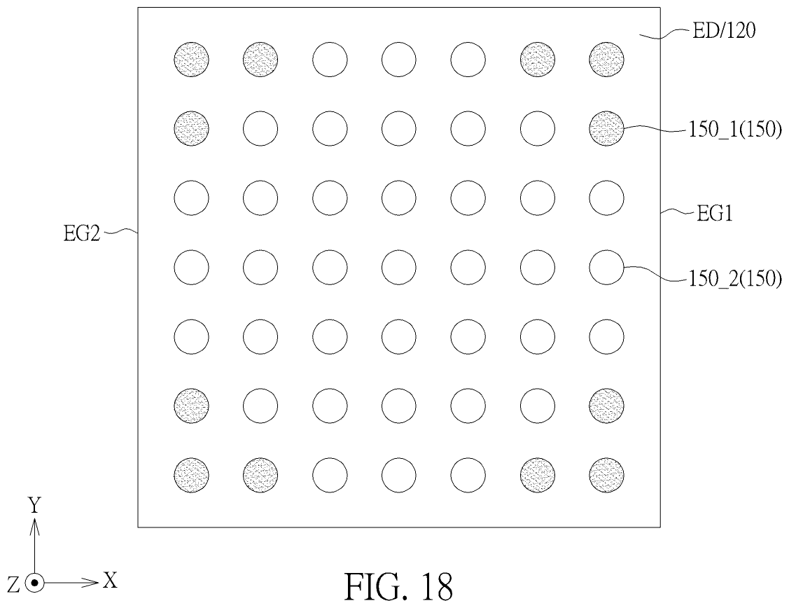

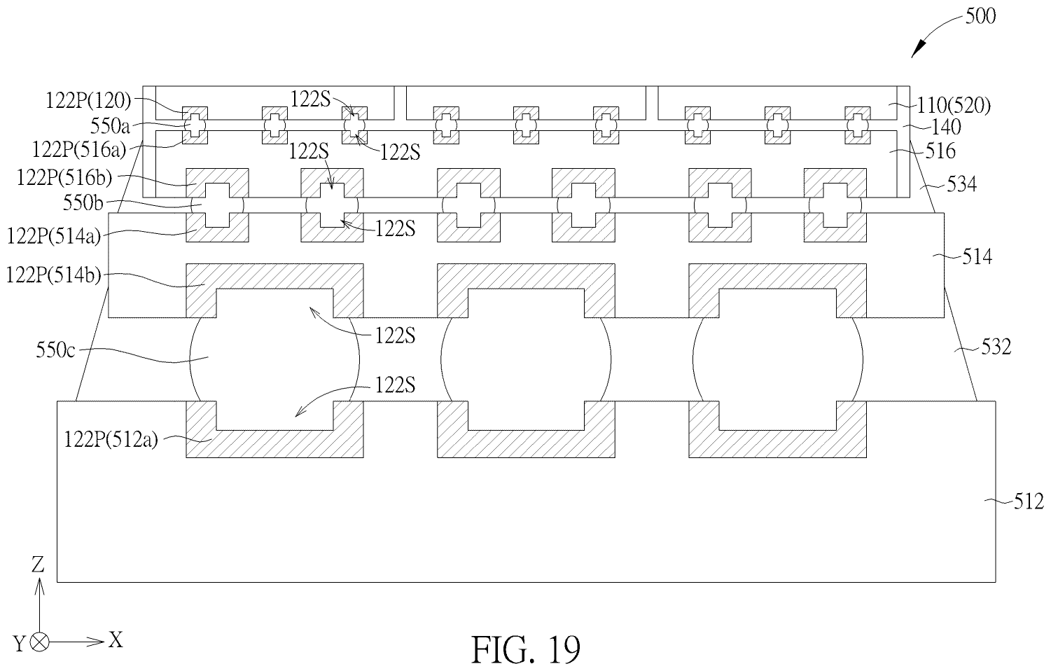

Furthermore, the design DS4 shown in FIG. 17 may be correspondingly adjusted according to the positions of the bonding component 150 and the conductive pattern 122P. For instance, the design DS4 shown in FIG. 17 may be applied to the bonding component 150 and the conductive pattern 122P which are adjacent to an edge or a corner of the electronic device (or an edge or a corner of the circuit structure 120), and the portion 150b of the bonding component 150 is closer to the edge or the corner of the electronic device (or the edge or the corner of the circuit structure 120) than the portion 150a of the bonding component 150 disposed in the recess 122S. Referring to FIG. 18, FIG. 18 is a schematic diagram showing a top view of an electronic device according to an embodiment of the present disclosure. In FIG. 18, the design DS4 shown in FIG. 17 may be applied to the bonding component 150_1 and its corresponding conductive pattern 122P which are adjacent to the corner of the electronic device ED (or the corner of the circuit structure 120), and other suitable design may be applied to other bonding components 150_2 and their corresponding conductive patterns 122P. Therefore, in FIG. 18, in the horizontal direction (e.g., the direction Y), the design of the bonding component 150_1 and its corresponding conductive pattern 122P which are adjacent to a right edge EG1 is symmetrical to the design of the bonding component 150_1 and its corresponding conductive pattern 122P which are adjacent to a left edge EG2, wherein the cross-sectional structure of the bonding component 150_1 and its corresponding conductive pattern 122P which are adjacent to a right edge EG1 may be the same as the design DS4 shown in FIG. 17 (i.e., the portion 150b of the bonding component 150_1 adjacent to the right edge EG1 may be in direct contact with the right side edge of the conductive pattern 122P, and the portion 150b of the bonding component 150_1 adjacent to the left edge EG2 may be in direct contact with the left side edge of the conductive pattern 122P), but not limited thereto. Based on this design, the bonding effect between the bonding component 150 adjacent to the edge of the electronic device ED (or the edge of the circuit structure 120) and the circuit structure 120 may be improved, so as to reduce the occurring possibility of damage (e.g., fracture) between the bonding component 150 and the circuit structure 120 at the edge of the electronic device ED (or the edge of the circuit structure 120), thereby strengthening the structure at the edge of the electronic device ED (or the edge of the circuit structure 120).

Note that the designs DS1, DS2, DS3 and DS4 shown in FIG. 17 may be applied to any of the above embodiments.

Referring to FIG. 19, FIG. 19 is a schematic diagram showing a cross-sectional view of an electronic device according to a fifth embodiment of the present disclosure, wherein the electronic device 500 shown in FIG. 19 may include a semiconductor packaging device formed by a 2.5D package process. As shown in FIG. 19, the electronic device 500 includes a plurality of electronic structures 520 and a plurality of substrates 512, 514 and 516. In the direction Z, the substrate 514 may be disposed on the substrate 512, the substrate 516 may be disposed on the substrate 514, and the electronic structures 520 may be disposed on the substrate 516. In some embodiments, the electronic structure 520 may include the aforementioned electronic component 110. In some embodiments, the substrates 512, 514 and 516 may individually include glass, quartz, ceramic, sapphire, silicon, polymer (e.g., PI, PET, etc.), other suitable material(s) or a combination thereof, and the substrates 512, 514 and 516 may have the same material or different material(s), but not limited thereto. For instance, the substrates 512, 514 and 516 are circuit boards, but not limited thereto.

In FIG. 19, the electronic structure 520 may be electrically connected to the conductive layer 516a of the substrate 516 through a bonding component 550a, the conductive layer 516b of the substrate 516 may be electrically connected to the conductive layer 514a of the substrate 514 through a bonding component 550b, and the conductive layer 514b of the substrate 514 may be electrically connected to the conductive layer 512a of the substrate 512 through a bonding component 550c.

In the present disclosure, the aforementioned design of the conductive pattern 122P having the recess 122S may be applied to at least one of the substrates 512, 514 and 516 and the electronic structures 520. For instance, in FIG. 19, the aforementioned conductive pattern 122P having the recess 122S may be applied to the substrates 512, 514 and 516 and the electronic structures 520. Thus, the aforementioned conductive pattern 122P having the recess 122S may be applied to the conductive layers 516a and 516b of the substrate 516, the conductive layers 514a and 514b of the substrate 514 and the conductive layer 512a of the substrate 512, the electronic structure 520 may further include the aforementioned circuit structure 120 disposed on a side of the electronic component 110, and the aforementioned conductive pattern 122P having the recess 122S may be applied to the conductive layer in the circuit structure 120. Accordingly, since the conductive pattern 122P having the recess 122S is be applied to the substrates 512, 514 and 516 and the electronic structure 520, the bonding effect of the bonding component 550c configured to bond the substrates 512 and 514, the bonding component 550b configured to bond the substrates 514 and 516 and the bonding component 550a configured to bond the substrate 516 and the electronic structure 520 are improved.

In FIG. 19, the packaging layer 140 may be configured to protect the electronic structure 520 and the substrate 516, so as to increase the yield rate of the electronic device 500. For instance, in FIG. 19, the packaging layer 140 may surround the electronic structure 520 and the substrate 516 and expose a surface of the electronic structure 520 opposite to the circuit structure 120, but not limited thereto.

Moreover, in FIG. 19, an underfill 532 may be disposed between the substrates 512 and 514, so as to protect the bonding component 550c between the substrates 512 and 514, thereby improving the yield rate of the electronic device 500. In FIG. 19, an underfill 534 may be disposed between the substrates 514 and 516, so as to protect the bonding component 550b between the substrates 514 and 516, hereby improving the yield rate of the electronic device 500. For instance, a Young's modulus of the underfill 532 may be different from a Young's modulus of the underfill 534, or the Young's modulus of the underfill 532 may be less than the Young's modulus of the underfill 534, but not limited thereto.

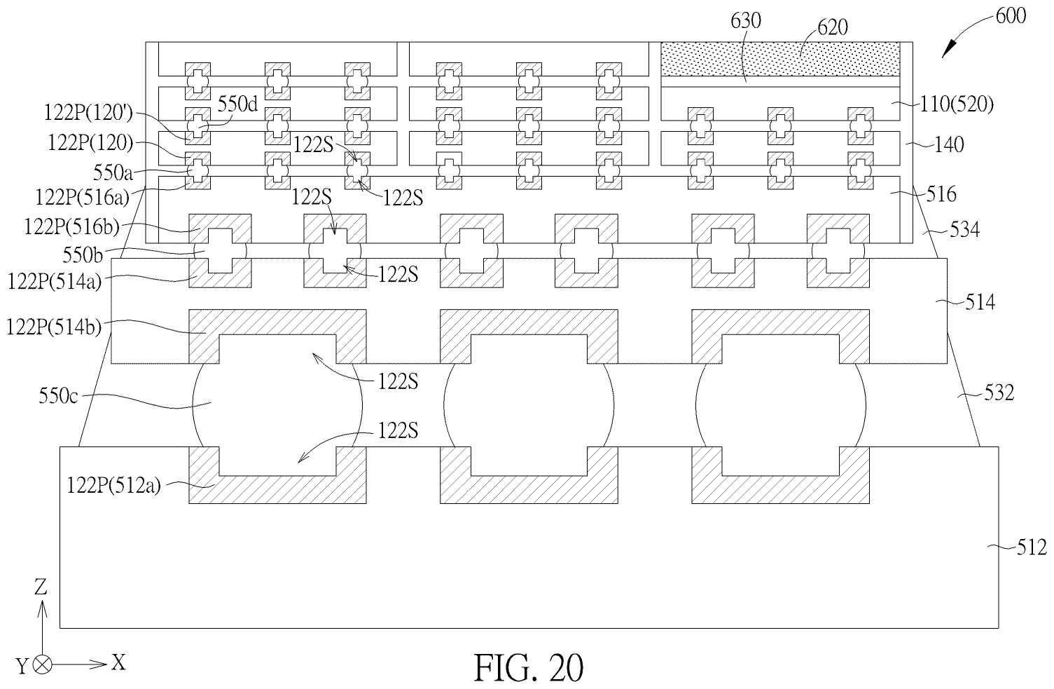

Referring to FIG. 20, FIG. 20 is a schematic diagram showing a cross-sectional view of an electronic device according to a sixth embodiment of the present disclosure. As shown in FIG. 20, a difference between this embodiment and the fifth embodiment is that the electronic device 600 may include a semiconductor packaging device formed by a 3D package process. Therefore, the electronic structures 520 may be stacked along the direction Z, and the electronic structures 520 may be electrically connected to each other through the bonding components 550d. In FIG. 20, at least one of the electronic structures 520 may have two circuit structures 120 and 120′, wherein the circuit structures 120 and 120′ may be respectively disposed on two opposite sides of the electronic structure 520 in the direction Z, such that the circuit structure 120 may be electrically connected to the electronic component disposed on a side of the electronic structure 520, and the circuit structure 120′ may be electrically connected to the electronic component disposed on another side of the electronic structure 520, so as to achieve the effect of stacking the electronic structures 520.

For instance, in FIG. 20, the aforementioned conductive pattern 122P having the recess 122S may be applied to the substrates 512, 514 and 516 and the electronic structures 520. Thus, the aforementioned conductive pattern 122P having the recess 122S may be applied to the conductive layers 516a and 516b of the substrate 516, the conductive layers 514a and 514b of the substrate 514 and the conductive layer 512a of the substrate 512, and may be applied to the conductive layers in the circuit structures 120 and 120′.

Optionally, the electronic device 600 may further include a dummy structure 620, wherein the dummy structure 620 may be disposed at a required position through any suitable process, so as to balance the packaging stresses. For instance, in FIG. 20, in the direction Z, the dummy structure 620 may be stacked on the electronic structure 520 through an adhesive layer 630, but not limited thereto. For instance, the dummy structure 620 may be electrically insulated from the electronic structure 520, but not limited thereto. A ratio of a CTE of the dummy structure 620 to a CTE of the electronic component 110 may be greater than or equal to 0.6 and less than or equal to 1.4, or greater than or equal to 0.8 and less than or equal to 1.2. The material of the dummy structure 620 may include silicon, glass, alloy, metal or a combination thereof, but not limited thereto.

Moreover, in FIG. 20, the packaging layer 140 may surround the electronic structure 520, the dummy structure 620 and the substrate 516 and expose a surface of the electronic structure 520 opposite to the circuit structure 120, and the packaging layer 140 may optionally expose a surface of the dummy structure 620 opposite to the adhesive layer 630, but not limited thereto.

In summary, since the present disclosure provides the conductive pattern having the recess, and the bonding component is disposed on the recess of the conductive pattern, the contact area between the bonding component and the circuit structure having the conductive pattern is enhanced, so as to improve the bonding effect between the bonding component and the circuit structure, thereby reducing the occurring possibility of damage (e.g., fracture) between the bonding component and the circuit structure, and increasing the yield rate of the electronic device.

Although the embodiments and their advantages of the present disclosure have been described as above, it should be understood that any person having ordinary skill in the art can make changes, substitutions, and modifications without departing from the spirit and scope of the present disclosure. In addition, the protecting scope of the present disclosure is not limited to the processes, machines, manufactures, material compositions, devices, methods and steps in the specific embodiments described in the description. Any person having ordinary skill in the art can understand the current or future developed processes, machines, manufactures, material compositions, devices, methods and steps from the content of the present disclosure, and then, they can be used according to the present disclosure as long as the same functions can be implemented or the same results can be achieved in the embodiments described herein. Thus, the protecting scope of the present disclosure includes the above processes, machines, manufactures, material compositions, devices, methods and steps. Moreover, each claim constitutes an individual embodiment, and the protecting scope of the present disclosure also includes the combination of each claim and each embodiment. The protecting scope of the present disclosure shall be determined by the appended claims.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
an electronic component;
a packaging layer surrounding the electronic component;
a circuit structure electrically connected to the electronic component, wherein the circuit structure comprises a conductive pattern; and
a bonding component overlapping the conductive pattern and disposed in a recess of the conductive pattern;
wherein the conductive pattern comprises a first portion, a second portion and a third portion, the third portion is connected to the first portion and the second portion, the bonding component overlaps the third portion, and a width of the first portion is different from a width of the second portion.

2. The electronic device of claim 1, wherein the second portion is closer to an edge of the electronic device than the first portion, and the width of the second portion is greater than the width of the first portion.

3. The electronic device of claim 1, wherein a total width is a sum of the width of the first portion, the width of the second portion and a width of the third portion, and a ratio of the width of the third portion to the total width is greater than or equal to 0.3 and less than or equal to 1.

4. The electronic device of claim 1, wherein the bonding component does not overlap the first portion and the second portion.

5. The electronic device of claim 1, wherein a ratio of a depth of the recess to a thickness of the first portion is greater than or equal to 0.1 and less than or equal to 0.4.

6. The electronic device of claim 1, wherein a depth of the recess is greater than a thickness of the first portion.

7. The electronic device of claim 1, wherein an angle between a sidewall of the recess and a normal direction of the electronic component is greater than or equal to 0 degrees and less than or equal to 75 degrees.

8. The electronic device of claim 1, wherein a sidewall of the recess has a V-shaped structure.

9. The electronic device of claim 1, wherein the circuit structure comprises an insulating layer, an opening exists between the insulating layer and the conductive pattern, and a portion of the bonding component is filled in the opening.

10. The electronic device of claim 1, further comprising a conductive layer disposed between the circuit structure and the bonding component, wherein the conductive layer is in direct contact with the recess of the conductive pattern.

11. The electronic device of claim 10, wherein a material of the conductive layer is a same as a material of the conductive pattern, and a particle size of the conductive layer is different from a particle size of the conductive pattern.

12. The electronic device of claim 10, wherein a material of the conductive layer is a same as a material of the conductive pattern, and a crystallinity of the conductive layer is different from a crystallinity of the conductive pattern.

13. The electronic device of claim 1, wherein the circuit structure is between the electronic component and the bonding component.

14. A manufacturing method of an electronic device, comprising:
providing a carrier substrate;
providing a barrier layer on the carrier substrate;
providing a circuit structure on the barrier layer, wherein a conductive pattern of the circuit structure overlaps the barrier layer;
removing the barrier layer to make the conductive pattern have a recess; and
providing a bonding component in the recess.

15. The manufacturing method of claim 14, further comprising:
providing a conductive layer and a release layer, wherein the conductive layer is between the release layer and the barrier layer.

16. The manufacturing method of claim 14, further comprising:
providing a conductive layer and a release layer, wherein the release layer is between the conductive layer and the barrier layer.

17. The manufacturing method of claim 14, wherein the barrier layer comprises metal.

18. The manufacturing method of claim 14, further comprising:
providing a conductive layer on the barrier layer;
wherein the conductive layer is disposed between the circuit structure and the barrier layer, and the conductive layer is in direct contact with the recess of the conductive pattern.

19. The manufacturing method of claim 18, wherein a material of the conductive layer is a same as a material of the conductive pattern, and a forming process of the conductive layer is different from a forming process of the conductive pattern.

20. The manufacturing method of claim 14, further comprising:
providing a blocking part on the carrier substrate, wherein the circuit structure comprises an insulating layer, and the blocking part is disposed between the insulating layer and the conductive pattern; and
removing the blocking part to make an opening be formed between the insulating layer and the conductive pattern;
wherein the bonding component is filled in the recess and the opening after providing the bonding component.
